(19) United States
(12) Patent Application Publication
(10) Pub. No.: US 2016/0043736 A1
(43) Pub. Date: Feb. 11, 2016

(54) SYSTEM AND METHOD TO CONCURRENTLY MATCH ANY TYPE, COMBINATION AND/OR RANGE OF CHARACTERS DEFINED BY A REGULAR EXPRESSION ON A HARDWARE IMPLEMENTATION USING A SINGLE DETECTION LOGIC

(71) Applicant: NXGN DATA, INC., Irvine, CA (US)

(72) Inventors: Ricardo Cassia, Rancho Santa Margarita, CA (US); Joao Alcantara, Irvine, CA (US); Kamyar Souri, San Jose, CA (US)

(21) Appl. No.: 14/816,964

(22) Filed: Aug. 3, 2015

Related U.S. Application Data
(60) Provisional application No. 62/034,066, filed on Aug. 6, 2014.

(51) Int. Cl. H03M 7/30

(52) U.S. Cl. CPC H03M 7/705; H03M 7/3084

(57) ABSTRACT

Method to simultaneously detect all possible types, combinations and/or ranges of characters of a Regular Expression search pattern in a search space by re-encoding the search pattern and the search space in single set bit representations, employing a single detection logic. The search space n-bit representation is re-encoded into a single set bit representation of 2n bits while single/multiple search pattern(s) n-bit representation(s) is (are) re-encoded and combined into a sole single/multiple set bit representation of 2n bits. The hardware implementation of the method detects the presence of any character existent from the search pattern in the search space.

### CROSS-REFERENCE TO RELATED APPLICATION(S)

The present application claims priority to and the benefit of U.S. Provisional Application No. 62/034,066, filed Aug. 6, 2014, entitled “SYSTEM AND METHOD TO CONCURRENTLY MATCH ANY TYPE, COMBINATION AND/OR RANGE OF CHARACTERS DEFINED BY A REGULAR EXPRESSION ON A HARDWARE IMPLEMENTATION USING A SINGLE DETECTION LOGIC”, the entire content of which is incorporated herein by reference.

### FIELD

One or more aspects of embodiments according to the present invention relate to a system and method to concurrently match any type, combination and/or range of characters defined by a regular expression on a hardware implementation using a single detection logic.

### BACKGROUND

In computer and machine-based telecommunications terminology, a character is a unit of information that roughly corresponds to a grapheme, grapheme-like unit, or symbol, such as in an alphabet or syllabary in the written form of a natural language. Examples of characters include letters, numerical digits, common punctuation marks (such as “.” or “-”), and whitespace. The concept also includes control characters, which do not correspond to symbols in a particular natural language, but rather to other bits of information used to process text in one or more languages. Examples of control characters include carriage return or tab, as well as instructions to printers or other devices that display or otherwise process text. Computers and communication equipment represent characters using a character encoding that assigns each character to something—an integer quantity represented by a sequence of digits, typically—that can be stored or transmitted through a network. Two examples of usual encodings are ASCII and the UTF-8 encoding for Unicode.

A text search is executed by comparing the encoded value of each character in the search pattern against the encoded value of each character in the search space. However, Regular Expressions make use of meta-characters to expand search capabilities. Each character in a Regular Expression is either understood to be a meta-character with its special meaning, or a regular character with its literal meaning Together, they can be used to identify textual material of a given pattern, or process a number of instances of it that can vary from a precise equality to a very general similarity of the pattern. For example, the meta-character “.” matches any single character. The meta-characters “[ ]”, known as a bracket expression, match a single character that is contained within the brackets, which includes fully specified characters as well as ranges of characters, i.e. [a-c] matches any single letter from the collection “a”, “b” or “c”.

Current hardware implementations use multiple single character comparators assisted by range comparators in order to find a positive match of a particular search pattern. The solution described here provides a hardware implementation to match any number of characters, contiguous or not in their representation, with a single comparator and concurrently.

### SUMMARY

Aspects of embodiments of the present disclosure are directed toward a system and method to concurrently match any type, combination and/or range of characters defined by a regular expression on a hardware implementation using a single detection logic.

### BRIEF DESCRIPTION OF THE DRAWINGS

These and other features and advantages of the present invention will be appreciated and understood with reference to the specification, claims and appended drawings wherein:

FIG. 1 is a character illustration diagram showing the character “a” (110), according to an embodiment of the present invention;

FIG. 2 is a character illustration diagram showing a regular expression for any vowel, according to an embodiment of the present invention;

FIG. 3 is a character illustration diagram showing a search pattern, according to an embodiment of the present invention; and

FIG. 4 is a flow chart showing a method that allows up to 256 characters to be searched in parallel, according to an embodiment of the present invention.

### DETAILED DESCRIPTION

The detailed description set forth below in connection with the appended drawings is intended as a description of exemplary embodiments of a System And Method To Concurrently Match Any Type, Combination And/Or Range Of Characters Defined By A Regular Expression On A Hardware Implementation Using A Single Detection Logic provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

### Keywords

Regular expression—sequence of characters that forms a search pattern, mainly for use in pattern matching with strings, or string matching

Character—letter or symbol represented by the combination of 8 bits based on a translation table, i.e. ASCII table.

ASCII—American Standard Code for Information Interchange character-encoding scheme.

Meta-characters—characters that have a special meaning instead of the literal meaning

Characters are encoded based on standard tables. The Extended ASCII, for example, uses 8 bits that can encode 256 different characters. This encoding mechanism will be used as a reference in the following description.

In a pure text search, a single 8 bit equality detection logic can be used in a hardware implementation to match each searched character from a string within the search space. However, Regular Expressions enable pattern search to match not only a single character per string character, but also from a collection of characters. The existing hardware implementations use multiple 8 bit comparators to perform the procedure. This limits the number of characters that can be searched concurrently to the number of comparators existent in the hardware. The solution described here enables a parallel search of any number or combination of characters for each character of the pattern string.

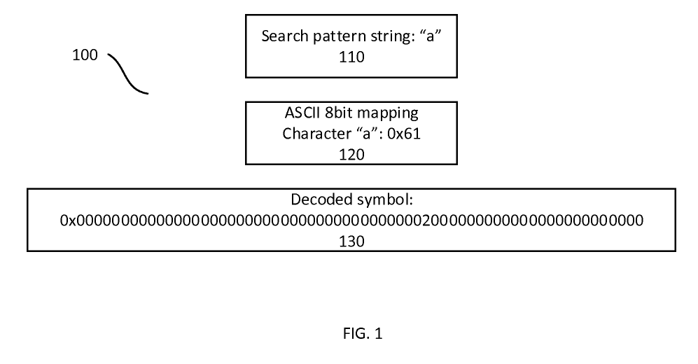

Every existent character in the predefined encoding standard is represented by a unique 8 bit symbol. The same character can be represented by a single bit set in a 256 bit (28) symbol. FIG. 1 (also referred to as “Picture 100” or “100”) shows an example of the character “a” (110). In the ASCII table, the character “a” is assigned to the 8 bit encoding value of 97, or 61 in hexadecimal (120). The 256 bit symbol is created by setting the 97th bit to ‘1’ (130). The construction of the 256 bit symbol is performed as a software preprocessing procedure. It comprises of parsing the Regular Expression string and creating the search patterns in the 256 bit representation before providing it to the detection hardware.

When both the search pattern character and the search space character follow the same decoding process, a 256 bit detection logic identifies a positive match in the same manner as to the comparison executed with 8 bit comparators.

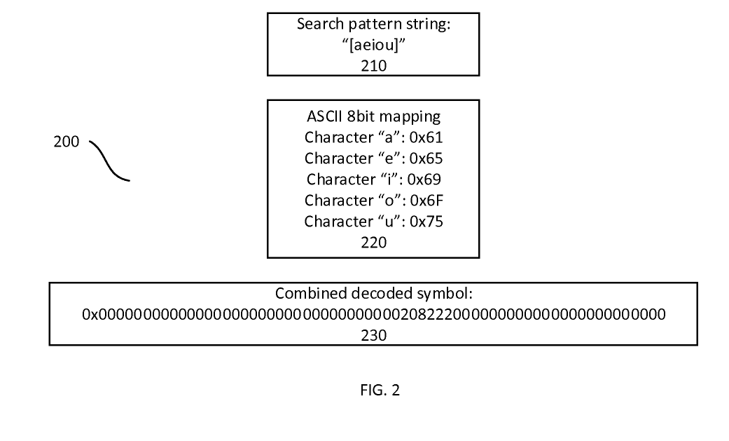

Furthermore, since in a 256 bit representation each character is described as a single bit set, multiple characters can be grouped and represented by a sole 256 bit symbol. FIG. 2 (also referred to as “Picture 200” or “200”) provides an example on how the search for vowels (characters “a”, “e”, “i”, “o” and “u”) can be represented in a Regular Expression (210), 8 bit encoded mappings (220), and the single 256 bit search pattern (230).

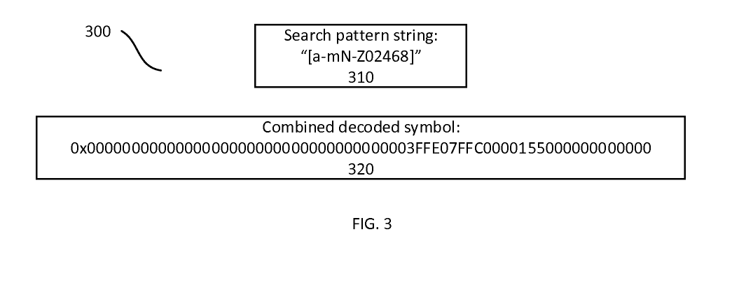

The search pattern “[a-mN-Z02468]” is a complex example. It will provide a positive match for a single character that falls into the range of lower case letters from “a” to “m”, or the range of upper case letters from “N” to “Z”, or the numbers “0”, “2”, “4”, “6” or “8”. The search pattern is depicted on FIG. 3 (also referred to as “Picture 300” or “300”), where the pattern is described on 310 and the combined decoded symbol is shown on 320.

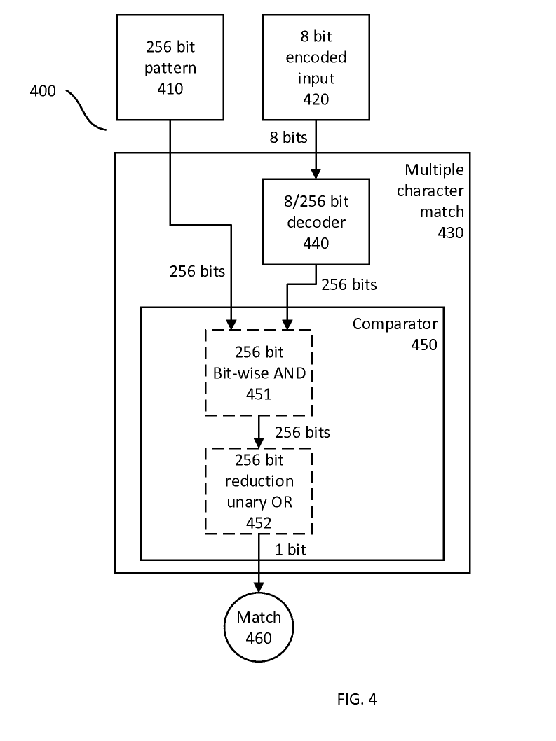

A positive match is defined if the correspondent asserted bit of the 256 bit representation of the search space character is also asserted in the 256 bits representation of the search pattern character. The method allows up to 256 characters to be searched in parallel. FIG. 4 (also referred to as “Picture 400” or “400”) shows an implementation of the method.

The pattern 410 is provided to the hardware as a result of the software preprocessing based on the input search pattern requested by the user, as described above. While the system feeds the match engine 430 with the original 8 bit encoded character 420, the decoder 440 generates the 256 bit representation of 420. The comparator 450 then performs a bit-wise AND operation between the 256 bit representations of the search pattern and the search space in 451. The 256 bit information computed in 451 is fed to 452. 452 performs a 256 bit reduction through a unary OR operation. 452 provides a single bit output that is asserted only in the event that any of the 256 bits of the input is asserted. A positive match 460 is true in case the output of 452 is asserted.

### Advantages/Benefits of Invention

An embodiment of the invention provides a mechanism that enables simple or complex patterns to be searched in the provided input, regardless of the number of possible alternatives in the pattern. The solution allows the hardware implementation to deterministically support all possible combinations of characters to be matched concurrently, while maintaining search performance constant, independently of the number or complexity of each character in a Regular Expression pattern string.

### Feasibility/Proof of Concept/Results Demonstration

An embodiment of the invention has been implemented in a Hardware Description Language and simulations can show the correctness of its functionality. It is currently being used (utilized) for Regular Expression pattern searches.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art. As used herein, the term “major component” means a component constituting at least half, by weight, of a composition, and the term “major portion”, when applied to a plurality of items, means at least half of the items.

As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Although exemplary embodiments of a system and method to concurrently match any type, combination and/or range of characters defined by a regular expression on a hardware implementation using a single detection logic have been specifically described and illustrated herein, many modifications and variations will be apparent to those skilled in the art. Accordingly, it is to be understood that a System And Method To Concurrently Match Any Type, Combination And/Or Range Of Characters Defined By A Regular Expression On A Hardware Implementation Using A Single Detection Logic constructed according to principles of this invention may be embodied other than as specifically described herein. The invention is also defined in the following claims, and equivalents thereof.

What is claimed is:

1. Method to detect simultaneously (or concurrently) all possible combinations of characters of a search pattern in a search space by re-encoding the search pattern and the search space in single set bit representations.

2. Method of claim 1, to re-encode search space n-bit representation into a single set bit representation of 2n bits.

3. Method of claim 1, to re-encode and combine single/multiple search pattern(s) n-bit representation(s) into a sole single/multiple set bit representation of 2n bits.

4. Method of claim 1, to detect the presence of any character existent from the search pattern in the search space, implemented based on a 2n-bit bit-wise AND operation followed by a reduction through a unary OR operation.

5. The logic of claim 4, wherein the hardware comprises a Regular Expression pattern detection.
